(19) United States
(12) Patent Application Publication
(10) Pub. No.: US 2019/0244824 A1
(43) Pub. Date: Aug. 8, 2019

(54) ARRAY SUBSTRATE, METHOD FOR FABRICATING THE SAME, DISPLAY PANEL AND METHOD FOR FABRICATING THE SAME

(71) Applicants: BOE TECHNOLOGY GROUP CO., LTD., Beijing (CN); ORDOS YUANSHENG OPTOELECTRONICS CO., LTD., Ordos (CN)

(72) Inventors: Haifeng XU, Beijing (CN); Dawei SHI, Beijing (CN); Liman PENG, Beijing (CN); Wentao WANG, Beijing (CN); Lu YANG, Beijing (CN); Lei YAO, Beijing (CN); Jinfeng WANG, Beijing (CN); Lei YAN, Beijing (CN); Jinjin XUE, Beijing (CN); Lin HOU, Beijing (CN); Fang YAN, Beijing (CN); Xiaowen SI, Beijing (CN); Zhijin MAN, Beijing (CN); Yaoda HOU, Beijing (CN); Yi LI, Beijing (CN); Lizhen ZHAO, Beijing (CN); Lei WANG, Beijing (CN)

(21) Appl. No.: 16/154,902

(22) Filed: Oct. 9, 2018

(30) Foreign Application Priority Data
Feb. 6, 2018 (CN) 201810115232.X

(51) Int. Cl. H01L 21/30; H01L 27/12

(52) U.S. Cl. CPC H01L 21/3003; H01L 27/1255; H01L 27/3265; H01L 27/1262; H01L 27/1288

(57) ABSTRACT

The present disclosure relates to an array substrate, a method for fabricating the same, a display panel, and a method for fabricating the same. The array substrate includes a substrate, an active layer on the substrate, a first insulating layer on the active layer, a gate electrode and a first electrode on the first insulating layer, wherein a projection of the first electrode on the substrate and a projection of the active layer on the substrate do not overlap, a third insulating layer on the first electrode, a projection of the third insulating layer on the substrate does not overlap with a projection of the active layer on the substrate, a second electrode on the third insulating layer, and a second insulating layer on the gate electrode and the second electrode.

### CROSS REFERENCE TO RELATED APPLICATIONS

This patent application claims the benefit and priority of Chinese Patent Application No. 201810115232.X filed on Feb. 6, 2018, the disclosure of which is incorporated by reference herein in its entirety as part of the present application.

### BACKGROUND

The present disclosure relates to a field of display technology. More specifically, it relates to an array substrate, a display panel, a method for fabricating an array substrate, and a method for fabricating a display panel.

Double-layer wirings are commonly used in an array substrate of the display product to form a capacitor to maintain a stable voltage. Generally, in the fabricating process of an array substrate, there is an adverse effect on the thin film transistor.

### BRIEF DESCRIPTION

Embodiments of the present disclosure provide an array substrate, a display panel, a method for fabricating the array substrate, and a method for fabricating the display panel.

Embodiments of the present disclosure provide an array substrate. The array substrate includes a substrate, an active layer on the substrate, a first insulating layer on the active layer, a gate electrode and a first electrode on the first insulating layer, a third insulating layer on the first electrode, a second electrode on the third insulating layer, and a second insulating layer on the gate electrode and the second electrode. A projection of the first electrode on the substrate does not overlap with a projection of the active layer on the substrate. A projection of the third insulating layer on the substrate does not overlap with a projection of the active layer on the substrate.

In an embodiment, the active layer includes polysilicon.

In an embodiment, the gate electrode and the first electrode are disposed in the same layer.

In an embodiment, the second insulating layer further covers the third insulating layer and the second electrode.

In an embodiment, the array substrate further includes source/drain electrodes disposed on the second insulating layer, the source/drain electrodes being in contact with the active layer through vias, and a planarization layer on the source/drain electrodes and the second insulating layer.

In an embodiment, the array substrate further includes a pixel defining layer on the planarization layer and a pixel light emitting unit defined by the pixel defining layer. The pixel light emitting unit includes a third electrode on the planarization layer, a light emitting layer on the third electrode, and a fourth electrode on the light emitting layer.

Embodiments of the present disclosure provide a display panel. The display panel includes the array substrate as described above.

Embodiments of the present disclosure provide a method for fabricating an array substrate. The method for fabricating the array substrate includes forming an active layer on a substrate, forming a first insulating layer on the active layer, forming a gate electrode and a first electrode on the first insulating layer, forming a third insulating layer on the first electrode, forming a second electrode on the third insulating layer, and forming a second insulating layer on the gate electrode and the second electrode. A projection of the first electrode on the substrate does not overlap with a projection of the active layer on the substrate. A projection of the third insulating layer on the substrate does not overlap with a projection of the active layer on the substrate.

In an embodiment, forming the third insulating layer includes forming a third insulating material layer on the gate electrode and the first electrode, and removing at least a portion of the projection of the third insulating material layer whose projection on the substrate overlaps with the projection of the active layer on the substrate to form the second insulating layer.

In an embodiment, the active layer includes polysilicon, and the method further includes performing hydrogenation treatment on the polysilicon after forming the second insulating layer.

In an embodiment, the hydrogenating treating includes annealing in a hydrogen atmosphere.

In an embodiment, forming the gate electrode and the first electrode includes forming a conductive layer on the active layer, and patterning the conductive layer to form the gate electrode and the first electrode.

In an embodiment, the method for fabricating the array substrate further includes forming source/drain electrodes on the second insulating layer, the source/drain electrodes being in contact with the active layer through vias, and forming a planarization layer on the source/drain electrodes and the second insulating layer.

In an embodiment, the method for fabricating the array substrate further includes forming, on the planarization layer, a pixel definition unit and a pixel light emitting unit defined by the pixel definition layer. Forming the pixel light emitting unit includes forming a third electrode on the planarization layer, forming a light emitting layer on the third electrode, and forming a fourth electrode on the light emitting layer.

Embodiments of the present disclosure provide a method for fabricating a display panel. The method for fabricating the display panel includes the method for fabricating the array substrate as described above.

### BRIEF DESCRIPTION OF THE DRAWINGS

In order to describe the technical solutions in the embodiments of the present disclosure more clearly, the accompanying drawings of the embodiments are briefly described below. It should be understood that the drawings described below refer only to some embodiments of the present disclosure, and not to restrict the present disclosure, wherein:

FIG. 1 is a schematic view of an array substrate according to an embodiment of the present disclosure;

FIG. 2 is a schematic view of an array substrate according to an embodiment of the present disclosure;

FIG. 3 is a schematic view of an array substrate according to an embodiment of the present disclosure;

FIG. 4 is a schematic view of an array substrate according to an embodiment of the present disclosure;

FIGS. 5A-5F are schematic views of a method for fabricating an array substrate according to an embodiment of the present disclosure;

FIGS. 6A-6E are schematic views of a method of forming a third insulating layer according to an embodiment of the present disclosure;

FIGS. 7A and 7B are schematic views of a method of forming a gate electrode and a first electrode, according to an embodiment of the present disclosure;

FIGS. 8A-8C are schematic views of a method for fabricating an array substrate according to an embodiment of the present disclosure;

FIGS. 9A-9E are schematic views of a method for fabricating an array substrate according to an embodiment of the present disclosure; and

FIG. 10 is a schematic view of a display panel according to an embodiment of the present disclosure.

### DETAILED DESCRIPTION

In order to make the technical solutions and advantages of the embodiments of the present disclosure more comprehensible, the technical solutions of the embodiments of the present disclosure are clearly and completely described below with reference to the accompanying drawings. Obviously, the described embodiments are only a part but not all of the embodiments of the present disclosure. Based on the described embodiments of the present disclosure, all other embodiments obtained by those skilled in the art without creative efforts shall also fall within the protection scope of the present disclosure.

As used herein and in the appended claims, the singular form of a word includes the plural, and vice versa, unless the context clearly dictates otherwise. Thus, the references “a”, “an”, and “the” are generally inclusive of the plurals of the respective terms. Similarly, the words “comprise”, “comprises”, and “comprising” are to be interpreted inclusively rather than exclusively.

For purposes of the description hereinafter, the terms “upper”, “lower”, “right”, “left”, “vertical”, “horizontal”, “top”, “bottom”, and derivatives thereof shall relate to the disclosure, as it is oriented in the drawing figures. The terms “overlying”, “atop”, “positioned on” or “positioned atop” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating, or semiconductor layers at the interface of the two elements.

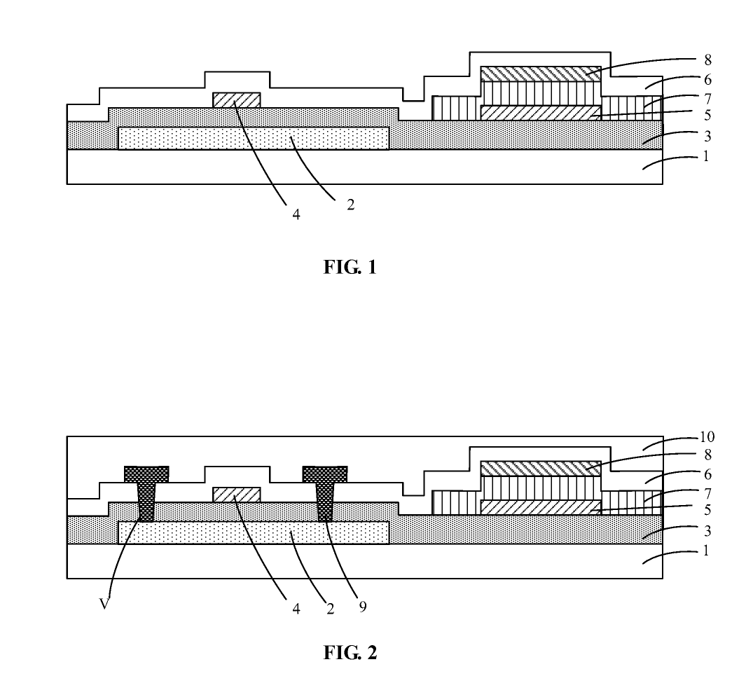

FIG. 1 is a schematic view of an array substrate according to an embodiment of the present disclosure. As shown in FIG. 1, an array substrate according to an embodiment of the present disclosure includes a substrate 1, an active layer 2 on the substrate 1, a first insulating layer 3 on the active layer 2, a gate electrode 4 and a first electrode 5 on the insulating layer 3, wherein a projection of the first electrode 5 on the substrate 1 does not overlap with a projection of the active layer 2 on the substrate 1, a third insulating layer 7 on the first electrode 5, a projection of the third insulating layer 7 on the substrate 1 does not overlap with a projection of the active layer 2 on the substrate 1, a second electrode 8 on the third insulating layer 7, and a second insulating layer 6 on the gate electrode 4 and the second electrode 8.

According to embodiments of the present disclosure, the first electrode 5 and the second electrode 8 form a capacitor. For example, when used in an OLED structure, the capacitor can maintain the stability of a voltage of the driving transistor in one cycle, so that the current of the OLED in one cycle is also stabilized. Therefore, the uniformity and stability of light emitting of the OLED can be ensured.

Furthermore, since the projection of the third insulating layer 7 between the first electrode 5 and the second electrode 8 on the substrate 1 does not overlap with the projection of the active layer 2 on the substrate 1, the effect of a subsequent process such as hydrogenation can be improved. The performance of the thin film transistor can be improved and the structure can be more compact.

In an embodiment, the active layer includes polysilicon. Compared with amorphous silicon, oxide semiconductor transistors and the like, a thin film transistor using polycrystalline silicon such as low temperature polycrystalline silicon has advantages such as high mobility and stability.

In an embodiment, as shown in FIG. 1, the gate electrode 4 may be disposed in the same layer as the first electrode 5. It should be understood that “disposed in same layer” in the present disclosure means being formed from the same material layer. Further, the second insulating layer 6 may also cover the third insulating layer 7 and the second electrode 8.

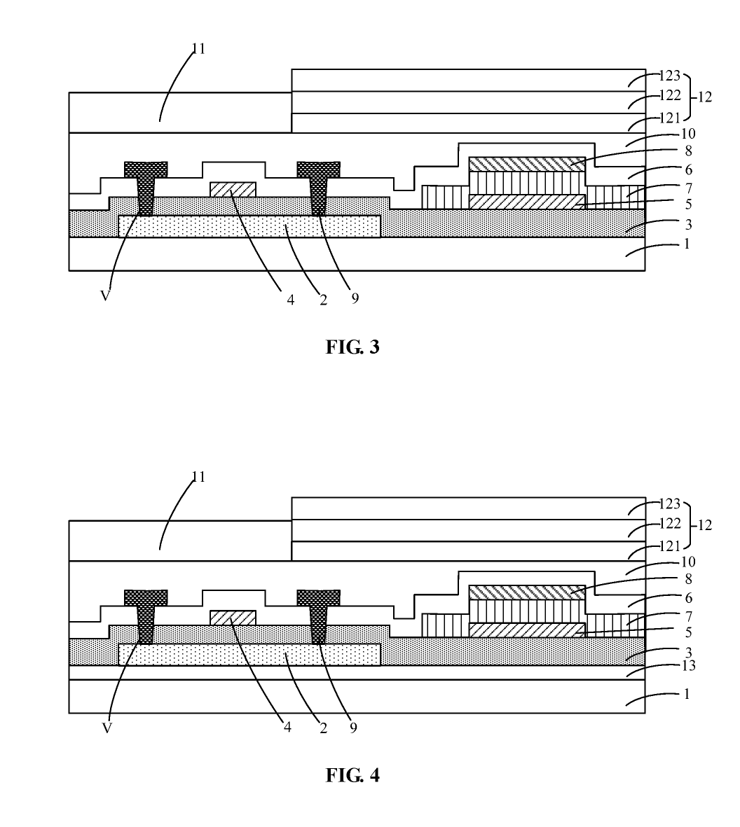

FIG. 2 is a schematic view of an array substrate according to an embodiment of the present disclosure. As shown in FIG. 2, in an embodiment, the array substrate may further include source/drain electrodes 9 disposed on the second insulating layer 6 and a planarization layer 10 on the source/drain electrodes 9 and the second insulating layer 6. The source/drain electrodes 9 are in contact with the active layer 2 through vias V.

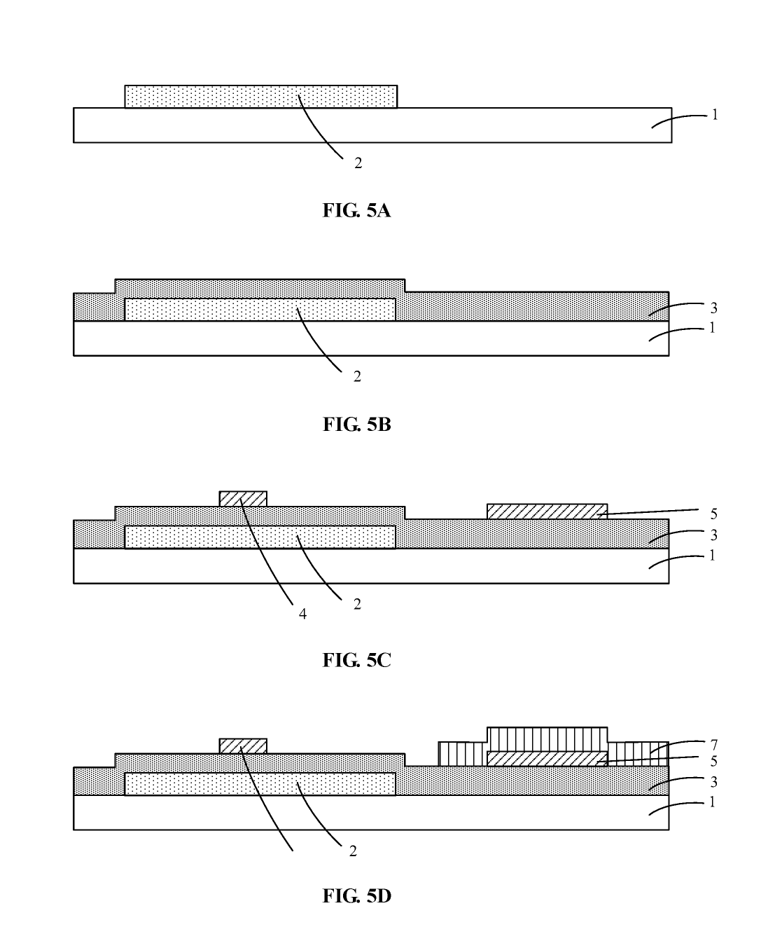

FIG. 3 is a schematic view of an array substrate according to an embodiment of the present disclosure. As shown in FIG. 3, in an embodiment, the array substrate may further include a pixel defining layer 11 on the planarization layer 10 and a pixel light emitting unit 12 defined by the pixel defining layer 11. The pixel light emitting unit 12 includes a third electrode 121 on the planarization layer 10, a light emitting layer 122 on the third electrode, and a fourth electrode 123 on the light emitting layer. One of the third electrode and the fourth electrode may be an anode, and the other of the third electrode and the fourth electrode may be a cathode. The light emitting layer may be an organic light emitting layer.

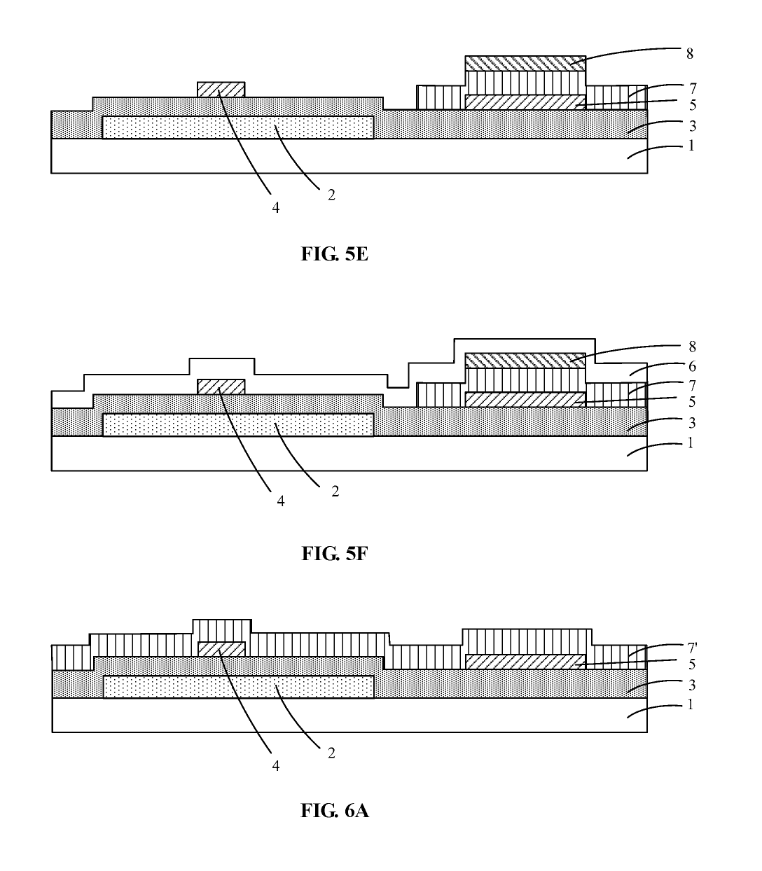

FIG. 4 is a schematic view of an array substrate according to an embodiment of the present disclosure. As shown in FIG. 4, in an embodiment, the array substrate may further include a buffer layer 13 between the substrate 1 and the active layer 2. A buffer layer facilitates reducing heat transfer and also prevents unwanted ions from entering the active region from the substrate.

Another aspect of the present disclosure also provides a method for fabricating an array substrate.

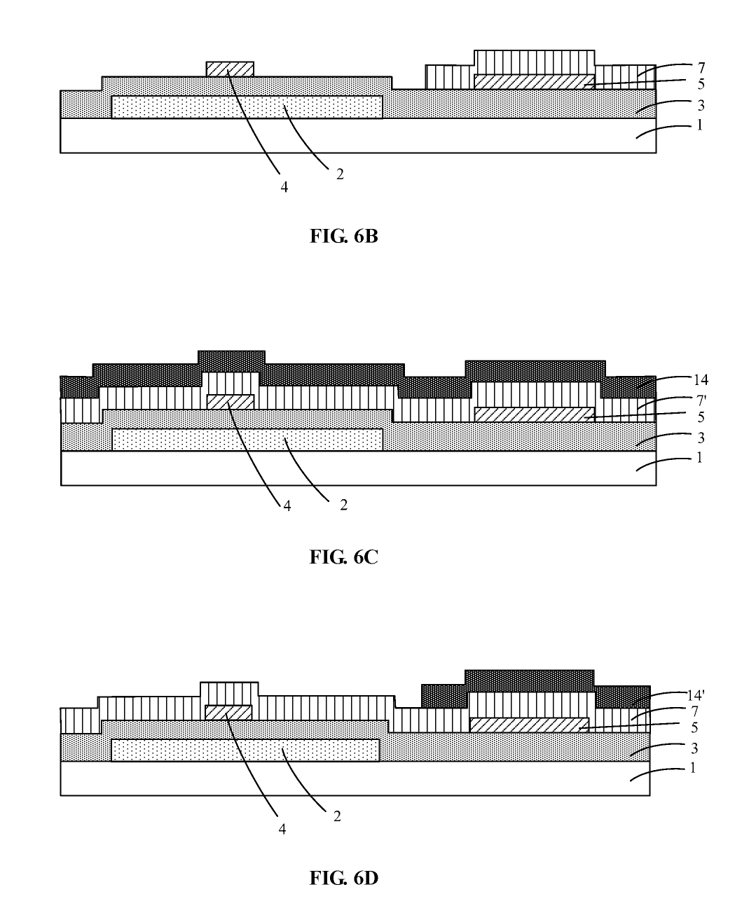

FIGS. 5A-5F are schematic views of a method for fabricating an array substrate according to an embodiment of the present disclosure. As shown in FIGS. 5A to FIGS. 5F, in an embodiment, the method for fabricating the array substrate may include:

S1: forming an active layer 2 on the substrate 1;

S3: forming a first insulating layer 3 on the active layer 2;

S5: forming a gate electrode 4 and a first electrode 5 on the first insulating layer 3, wherein the projection of the first electrode 5 on the substrate 1 does not overlap with the projection of the active layer 2 on the substrate 1;

S7: forming a third insulating layer 7 on the first electrode 5, wherein the projection of the third insulating layer 7 on the substrate 1 does not overlap with the projection of the active layer 2 on the substrate 1;

S9: forming a second electrode 8 on the third insulating layer 7; and

S11: forming a second insulating layer 6 on the gate electrode 4 and the second electrode 8.

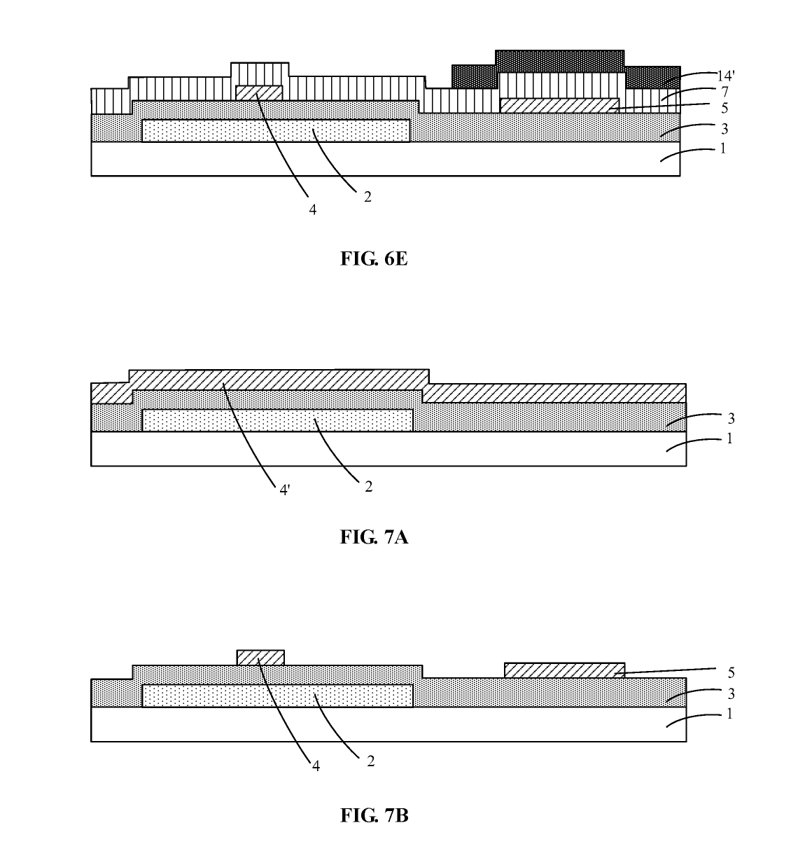

FIGS. 6A-6E are schematic flow views of a method of forming a third insulating layer according to an embodiment of the present disclosure.

As shown in FIG. 6A and FIG. 6B, in an embodiment of the present disclosure, forming the third insulating layer includes:

S71: forming a third insulating material layer 7′ on the gate electrode 4 and the first electrode 5; and

S73: removing at least a portion of the third insulating material layer 7′ whose projection on the substrate 1 overlaps with the projection of the active layer 2 on the substrate 1 to form the second insulating layer 7.

As shown in FIGS. 6C-6E, removing at least a portion of the third insulating material layer 7′ whose projection on the substrate 1 overlaps with the projection of the active layer 2 on the substrate 1 includes:

S731: as shown in FIG. 6C, applying (for example, coating) a photoresist 14 on the third insulating material layer 7′;

S732: as shown in FIG. 6D, patterning the photoresist 14 (for example, exposing and developing), leaving only a portion of the photoresist 14 above the first electrode 5, that is, the photoresist retention portion 14′;

S733: as shown in FIG. 6E, using the photoresist retaining portion 14′ as a mask layer, removing a portion of the third insulating material layer 7′ that is not covered by the photoresist retaining portion 14′; and

S734: removing the photoresist remaining portion 14′ to form the structure shown in FIG. 6B.

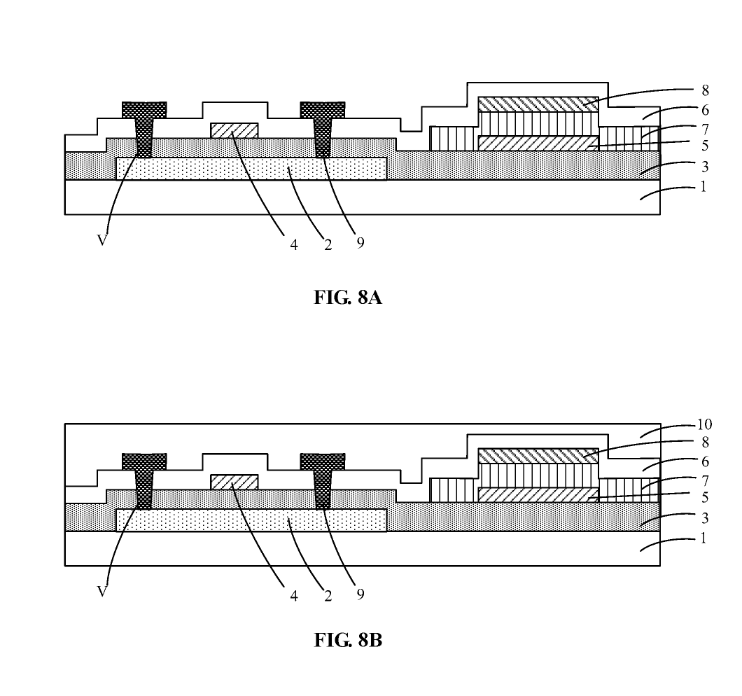

FIGS. 7A and 7B are schematic views of a method of forming a gate electrode and a first electrode according to an embodiment of the present disclosure. In an embodiment, forming the gate electrode and the first electrode includes:

S51: as shown in FIG. 7A, forming a conductive layer 4′ on the active layer; and

S53: as shown in FIG. 7B, patterning the conductive layer 4′ to form the gate electrode 4 and the first electrode 5.

That is, the gate electrode and the first electrode may be disposed in the same layer.

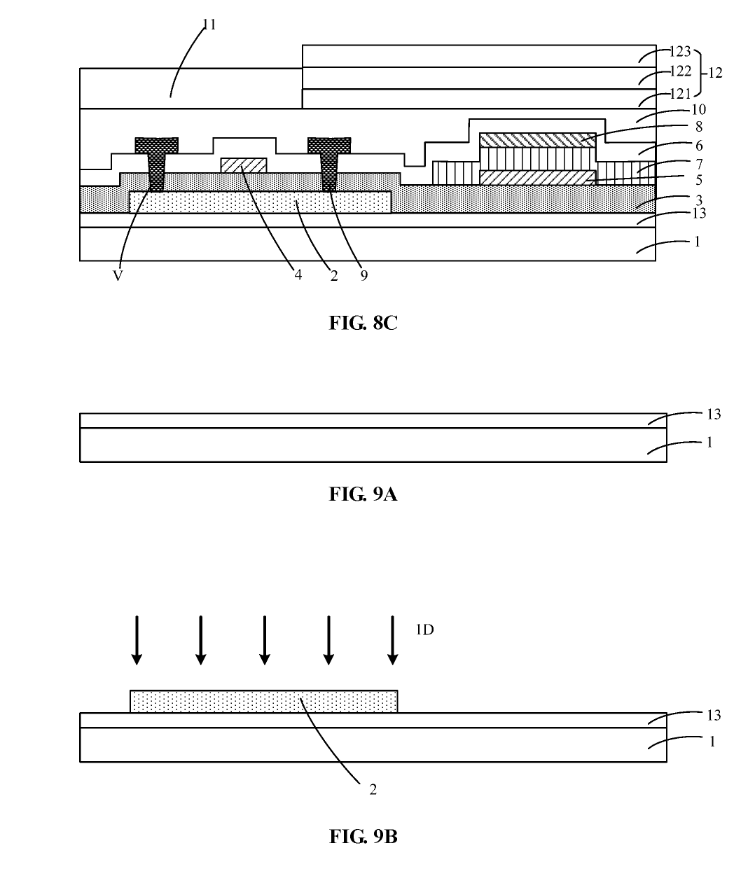

FIGS. 8A-8C are schematic views of a method for fabricating an array substrate according to an embodiment of the present disclosure.

The method for fabricating the array substrate according to the embodiment of the present disclosure may further include:

S13: as shown in FIG. 8A, source/drain electrodes 9 are formed on the second insulating layer 6, and the source/drain electrodes 9 are in contact with the active layer 2 through the vias V;

S15: as shown in FIG. 8B, forming a planarization layer 10 on the source/drain electrodes 9 and the second insulating layer 6;

S17: as shown in FIG. 8C, forming a pixel defining layer 11 and a pixel light emitting unit 12 defined by the pixel defining layer 11 on the planarization layer 10. Forming the pixel light emitting unit 11 includes forming a third electrode 121 on the planarization layer 10, forming a light-emitting layer 122 on the third electrode 121, and forming a fourth electrode 123 on the light-emitting layer 122. The third electrode 121 may be an anode, the light emitting layer 122 may be an organic light emitting layer, and the fourth electrode 123 may be a cathode.

In an embodiment, the active layer includes polysilicon. Thin film transistors including polycrystalline silicon such as low temperature polysilicon have advantages such as higher mobility and stability than amorphous silicon, oxide semiconductor transistors and the like. Forming the active layer may include forming an amorphous silicon layer on the substrate, annealing the amorphous silicon layer (for example, using excimer laser annealing) to form a polysilicon layer.

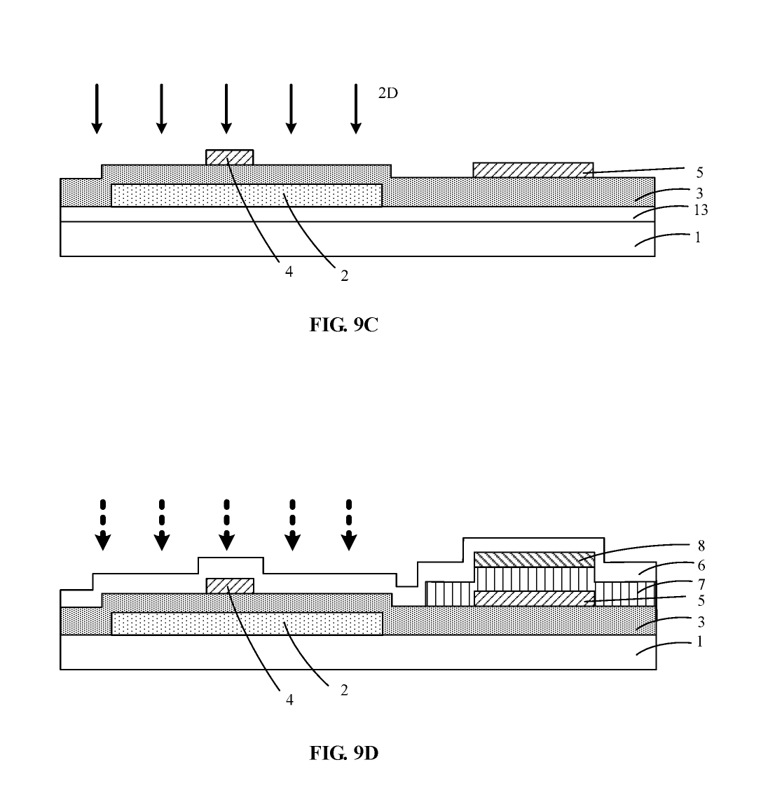

FIGS. 9A-9E are schematic views of a method for fabricating an array substrate according to an embodiment of the present disclosure. As shown in FIG. 9A, in an embodiment, the method for fabricating the array substrate further includes SO: forming a buffer layer 13 on the substrate 1 before forming the active layer 2. The buffer layer facilitates reducing heat transfer and also prevents unwanted ions from entering the active region from the substrate.

As shown in FIG. 9B, the method for fabricating an array substrate according to an embodiment of the present disclosure may further include

S2: performing a doping with a first conductivity type (1D) on the active layer 2 before forming the first insulating layer 3 (S3).

As shown in FIG. 9C, the method for fabricating an array substrate according to an embodiment of the present disclosure further includes S4: after forming the gate electrode 4, performing a doping with a second conductivity type (2D) on the active layer 2 to form source/drain regions of the active layer 2.

As shown in FIG. 9D, the method for fabricating an array substrate according to an embodiment of the present disclosure further includes performing an activation process after performing a doping with the second conductivity type (2D) on the active layer 2. The activation treatment may be performed after the formation of the second insulating layer 6. For example, a high temperature annealing rapid process can be employed for the activation process. By the activation treatment, lattice damage of the active layer 2 (for example, a polysilicon layer) caused by doping such as ion implantation can be repaired.

As shown in FIG. 9E, the method for fabricating an array substrate according to an embodiment of the present disclosure further includes S8: after forming the second insulating layer 6 (for example, after the activation process), hydrogenating the polysilicon. The hydrogenating treatment may include annealing in a hydrogen atmosphere. By hydrogenation, dangling bonds and interface traps in the grain boundaries of the active layer such as polysilicon can be reduced, and the field effect mobility, the on-state current, and the off-state current of the transistor can be improved, thereby improving the performance of the transistor.

Since the projection of the third insulating layer 7 between the first electrode 5 and the second electrode 8 on the substrate 1 does not overlap with the projection of the active layer 2 on the substrate 1, hydrogen does not need to pass through the third insulating layer 7 into the active layer 2, this can shorten the diffusion distance of hydrogen, improve the hydrogenation effect, and thus improve the performance of the transistor.

Embodiments of the present disclosure also provide a display panel including the array substrate as described above. Embodiments of the present disclosure also provide a method for fabricating a display panel, including the method for fabricating an array substrate as described above.

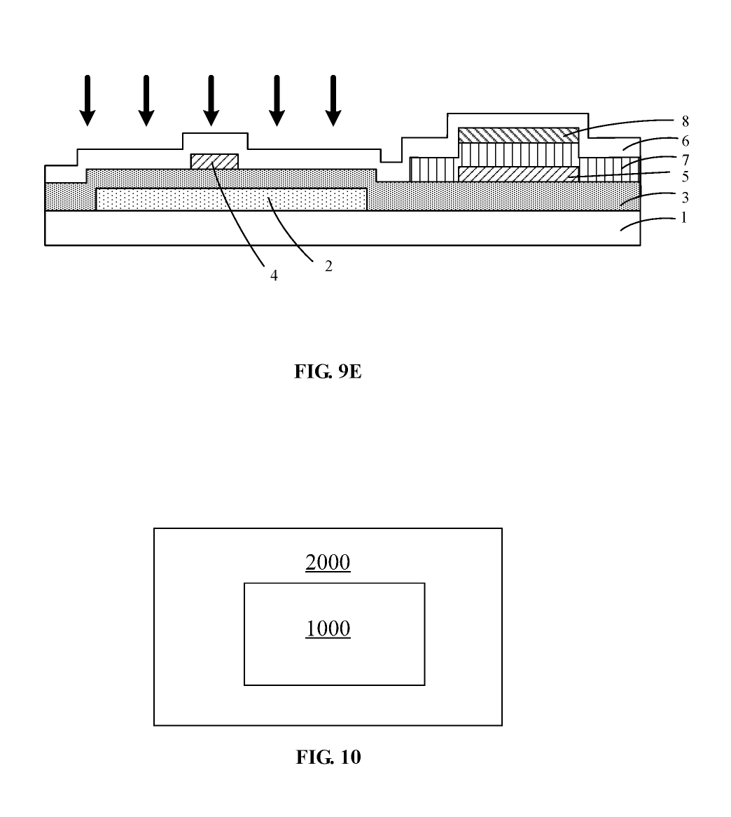

FIG. 10 is a schematic view of a display panel according to an embodiment of the present disclosure. As shown in FIG. 10, a display panel 2000 according to an embodiment of the present disclosure includes an array substrate 1000. The array substrate 1000 may be an array substrate as shown in FIGS. 1, 2, 3, and 4.

The display device provided by the embodiment of the present disclosure may be any display product, component such as a display panel, a mobile phone, a tablet computer, a television, a notebook computer, a digital photo frame, a navigator, and the like.

Having described certain specific embodiments, these embodiments have been presented by way of example only, and are not intended to limit the scope of the present disclosure. Indeed, the novel embodiments described herein may be embodied in various other forms, furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

1. An array substrate comprising:
a substrate;
an active layer on the substrate;
a first insulating layer on the active layer;
a gate electrode and a first electrode on the first insulating layer, wherein a projection of the first electrode on the substrate does not overlap with a projection of the active layer on the substrate;
a third insulating layer on the first electrode, wherein a projection of the third insulating layer on the substrate does not overlay with a projection of the active layer on the substrate;
a second electrode on the third insulating layer; and
a second insulating layer on the gate electrode and the second electrode.

2. The array substrate according to claim 1, wherein the active layer comprises polysilicon.

3. The array substrate according to claim 1, wherein the gate electrode and the first electrode are disposed in the same layer.

4. The array substrate according to claim 1, wherein the second insulating layer further covers the third insulating layer and the second electrode.

5. The array substrate according to claim 4, further comprising source/drain electrodes disposed on the second insulating layer, the source/drain electrodes in contact with the active layer through vias; and
a planarization layer on the source/drain electrodes and the second insulating layer.

6. The array substrate according to claim 5, further comprising a pixel defining layer on the planarization layer and a pixel light emitting unit defined by the pixel defining layer, wherein the pixel light emitting unit comprises:
a third electrode on the planarization layer;
a light emitting layer on the third electrode; and
a fourth electrode on the light emitting layer.

7. A display panel comprising the array substrate according to claim 1.

8. A method for fabricating an array substrate, the method comprising:
forming an active layer on a substrate;
forming a first insulating layer on the active layer;
forming a gate electrode and a first electrode on the first insulating layer, wherein a projection of the first electrode on the substrate does not overlap with a projection of the active layer on the substrate;
forming a third insulating layer on the first electrode, wherein a projection of the third insulating layer on the substrate does not overlap with a projection of the active layer on the substrate;
forming a second electrode on the third insulating layer; and
forming a second insulating layer on the gate electrode and the second electrode.

9. The method for fabricating an array substrate according to claim 8, wherein forming the third insulating layer comprises:
forming a third insulating material layer on the gate electrode and the first electrode; and
removing at least a portion of the third insulating material layer whose projection on the substrate overlaps with the projection of the active layer on the substrate to form the second insulating layer.

10. The method for fabricating an array substrate according to claim 9, wherein the active layer comprises polysilicon, and wherein the method further comprises performing hydrogenation treatment on the polysilicon after forming the second insulating layer.

11. The method for fabricating an array substrate according to claim 10, wherein the hydrogenation treatment comprises annealing in a hydrogen atmosphere.

12. The method for fabricating an array substrate according to claim 8, wherein forming the gate electrode and the first electrode comprises:
forming a conductive layer on the active layer: and
patterning the conductive layer to form the gate electrode and the first electrode.

13. The method for fabricating an array substrate according to claim 8, further comprising:
forming source/drain electrodes on the second insulating layer, the source/drain electrodes in contact with the active layer through vias; and
forming a planarization layer on the source/drain electrodes and the second insulating layer.

14. The method for fabricating an array substrate according to claim 13, the method further comprising:
forming a pixel definition unit and a pixel light emitting unit defined by the pixel definition layer on the planarization layer, wherein forming the pixel light emitting unit comprises:
forming a third electrode on the planarization layer;
forming a light emitting layer on the third electrode; and
forming a fourth electrode on the light emitting layer.

15. A method for fabricating a display panel comprising the method for fabricating the array substrate according to claim 8.

16. A display panel comprising the array substrate according to claim 2.

17. A display panel comprising the array substrate according to claim 3.

18. A display panel comprising the array substrate according to claim 4.

19. A display panel comprising the array substrate according to claim 5.

20. A display panel comprising the array substrate according to claim 6.
